(19) United States
(12) Patent Application Publication
(10) Pub. No.: US 2004/0046237 A1
(43) Pub. Date: Mar. 11, 2004

(54) Lead frame and method of manufacturing the same

(75) Inventors: Akinobu Abe, Nagano (JP); Tetsuichiro Kasahara, Nagano (JP); Kesayuki Sonehara, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: SHINKO ELECTRIC INDUSTRIES CO., LTD, Nagano-shi (JP)

(21) Appl. No.: 10/653,936

(22) Filed: Sep. 4, 2003

(30) Foreign Application Priority Data
Sep. 5, 2002 (JP) 2002-259585

(51) Int. Cl. H01L 23/495

(52) U.S. Cl. 257/676; 257/673; 438/123

(57) ABSTRACT

A lead frame includes a frame portion and a plurality of land-like conductor portions arranged in a lattice pattern in a region within the frame portion. The frame portion and the land-like conductor portions are supported by an adhesive tape. Each of the land-like conductor portions is formed of part of each of a plurality of leads at a portion where each lead intersects each other, the plurality of leads being discontinuously arranged so as to be orthogonal to each other. Each portion where the leads intersect each other is formed to be larger than a width of the corresponding lead.

### BACKGROUND OF THE INVENTION

(a) Field of the Invention

The present invention relates to a lead frame used as a substrate of a package (semiconductor device) for mounting a semiconductor element thereon. More particularly, the present invention relates to a lead frame which is used in a leadless package such as a Quad Flat Non-leaded package (QFN) and has a shape adapted to allow a semiconductor element (chip) to be mounted thereon regardless of a size of the chip, and to a method of manufacturing the lead frame.

(b) Description of the Related Art

FIGS. 1A to 1C schematically show constitutions of a prior art lead frame and a semiconductor device using the same.

FIG. 1A shows a constitution of part of a strip-like lead frame 10 as viewed in a plane. This lead frame 10 has a frame structure including an outer frame portion 11 and inner frame portions (also referred to as “section bars”) 12 arranged in a matrix within the outer frame portion 11. The outer frame portion 11 is provided with guide holes 13 which are engaged with a conveyor mechanism when the lead frame 10 is conveyed. In the center of each opening defined by the frame portions 11 and 12, a tetragonal die-pad portion 14 on which a semiconductor element (chip) is to be mounted is arranged. This die-pad portion 14 is supported by four support bars 15 extending from four corners of the corresponding frame portions 11, 12. A plurality of beam-shaped leads 16 extend in a comb shape from each of frame portions 11, 12 toward the die-pad portion 14. Each of the leads 16 includes an inner lead portion 16a (FIG. 1B) which is electrically connected to an electrode terminal of the chip to be mounted and an outer lead portion (external connection terminal) 16b which is electrically connected to a wiring of a mounting board such as a mother board. Broken lines CL indicate dividing lines when the lead frame 10 is finally divided into packages (semiconductor devices) in a package assembly process. Although not shown in FIG. 1A, the entire section bar (inner frame 12) is removed when dividing into packages.

FIG. 1B shows a cross-sectional structure of a semiconductor device 20 with a QFN package structure which is manufactured using the lead frame 10. In the semiconductor device 20, reference numeral 21 denotes a semiconductor element mounted on the die-pad portion 14; reference numeral 22 denotes a bonding wire connecting each electrode terminal of the semiconductor element 21 to the inner lead portion 16a of the corresponding lead 16; and the reference numeral 23 denotes sealing resin for protecting the semiconductor element 21, the bonding wire 22, and the like. The outer lead portion 16b used as the external connection terminal of the lead 16 is exposed to a mounting side of the semiconductor device 20 as shown in FIG. 1B.

In manufacturing the semiconductor device 20 (QFN package), a basic process thereof includes a step (die bonding) of mounting the semiconductor element 21 on the die-pad portion 14 of the lead frame 10, a step (wire bonding) of electrically connecting each electrode terminal of the semiconductor element 21 to the corresponding lead 16 of the lead frame 10 with the bonding wire 22, a step (molding) of sealing the semiconductor device 21, the bonding wire 22, and the like, with the sealing resin 23, and a step (dicing) of dividing the lead frame 10 into packages (semiconductor devices 20) with a dicer or the like.

In wire bonding, as schematically shown in FIG. 1C, the electrode terminals 21a of the semiconductor element 21 are connected to the corresponding leads 16 with a one-to-one relationship by the bonding wires 22.

According to the constitution of the prior art lead frame (FIGS. 1A to 1C) as described above, the leads 16 as the external connection terminals extend in a comb shape from the frame portions 11, 12 toward the die-pad portion 14. Therefore, when further increasing the number of terminals, it is necessary to narrow both the width of each lead and the interval between the leads, or to enlarge the size of the lead frame with keeping the size of each lead or the like.

However, the technique of narrowing the width of each lead accompanies a difficulty in a technical aspect (etching, stamping, or the like, for patterning the lead frame). On the other hand, the technique of enlarging the size of the lead frame introduces a disadvantage in that the material cost thereof is increased. Namely, in the prior art lead frame with the beam-shaped leads (external connection terminals) extending in a comb shape from the frame portions toward the die-pad portion, there has been a problem in that the demand for increasing the number of terminals is not necessarily satisfied.

The applicant of this application has proposed one approach to solve such a problem (Japanese Patent Application No. 2001-262876, laid open on Mar. 14, 2003 (Japanese Patent Laid-Open No. 2003-78094)). The specification and drawings of this application describe a lead frame including a plurality of land-like external connection terminals arranged in a lattice pattern in a region between the frame portions and the die-pad portion, instead of the prior art beam-shaped leads. According to the lead frame, the number of terminals can be relatively increased compared with the prior art lead frame with the beam-shaped leads (external connection terminals) extending in a comb shape.

The lead frame is provided with the die-pad portion as in the prior art. The size (area occupied in the lead frame) of the die-pad portion is fixedly determined in accordance with the size of the semiconductor element (chip) to be mounted. In other words, one lead frame corresponds to one type of chip size. Therefore, there is a disadvantage in that it is required to manufacture a lead frame in exclusive use for each type of chip to be mounted, and thus there is room for improvement.

### SUMMARY OF THE INVENTION

An object of the present invention is to provide a lead frame which can cope with a plurality of sizes of semiconductor elements (chips) to be mounted, independently of the sizes thereof and to provide a method of manufacturing the lead frame. Moreover, the lead frame allows a plurality of chips to be mounted in one package (semiconductor device) and also contributes to an increase in the number of terminals.

To attain the above object, according to one aspect of the present invention, there is provided a lead frame including a frame portion, and a plurality of land-like conductor portions arranged in a lattice pattern within a region surrounded by the frame portion, wherein the frame portion and the plurality of land-like conductor portions are supported by an adhesive tape.

According to the constitution of the lead frame of this aspect, since the plurality of land-like conductor portions are arranged in a lattice pattern within the region surrounded by the frame portion, some of the land-like conductor portions can be used as a substitute for a die-pad portion in accordance with the size of a semiconductor element (chip) to be mounted. Namely, instead of a prior art die-pad portion whose size is fixedly determined in accordance with the chip size, the plurality of land-like conductor portions are arranged in a lattice pattern and the necessary number of land-like conductor portions can be substituted for the die-pad portion. Accordingly, it is possible to cope with a plurality of chip sizes using one lead frame, independently of the chip sizes.

Also, since the lead frame allows chips with arbitrary sizes to be mounted, a plurality of chips can be mounted in one package (semiconductor device).

Furthermore, since the plurality of land-like conductor portions (some of them are used as a substitute for the die-pad portion) used as external connection terminals are arranged in a lattice pattern within the region surrounded by the frame portion, the number of terminals can be relatively increased compared with the prior art lead frame with beam-shaped leads (corresponding to the external connection terminals) extending in a comb shape from the frame portion toward the die-pad portion (realization of chips with terminals increased).

Also, according to another aspect of the present invention, there is provided a method of manufacturing a lead frame, including the steps of: forming a base frame including a frame portion and a plurality of leads which are arranged in a direction orthogonal to each other within a region surrounded by the frame portion and connected to the frame portion, by etching or stamping a metal plate; forming recess portions by half etching, at portions other than portions where the leads intersect each other and the frame portion, of one surface of the base frame; attaching an adhesive tape to the surface of the base frame where the recess portions are formed; and cutting off portions of the leads where the recess portions are formed.

According to the method of manufacturing a lead frame of this aspect, the portions of the leads where the recess portions are formed are finally cut off so as to form a structure including the leads discontinuously arranged to be orthogonal to each other. In other words, the lead frame is realized in which the land-like conductor portions, each being formed of part of the corresponding lead at the portion where each lead intersects each other, are arranged in a lattice pattern within the region surrounded by the frame portion. Therefore, the effect similar to that of the lead frame according to the above aspect can be obtained.

### BRIEF DESCRIPTION OF THE DRAWINGS

FIGS. 1A to 1C are views showing constitutions of a prior art lead frame and a semiconductor device using the same;

FIGS. 2A and 2B are views showing a constitution of a lead frame according to an embodiment of the present invention;

FIG. 3 is a plan view showing an example of a manufacturing process of the lead frame of FIGS. 2A and 2B;

FIGS. 4A to 4D are cross-sectional views (partially, plan view) showing the manufacturing process following the process of FIG. 3;

FIG. 5 is a plan view showing an example of arrangement (arrangement of the chip mounting region) of chips with arbitrary sizes for the lead frame of FIGS. 2A and 2B;

FIG. 6 is a plan view showing another example of arrangement (arrangement of the chip mounting region) of chips with arbitrary sizes for the lead frame of FIGS. 2A and 2B;

FIGS. 7A to 7C are views schematically showing an example of a semiconductor device manufactured using the lead frame of FIGS. 2A and 2B; and

FIGS. 8A to 8C are cross-sectional views showing another example of the manufacturing process of the lead frame of FIGS. 2A and 2B.

### DESCRIPTION OF THE PREFERRED EMBODIMENTS

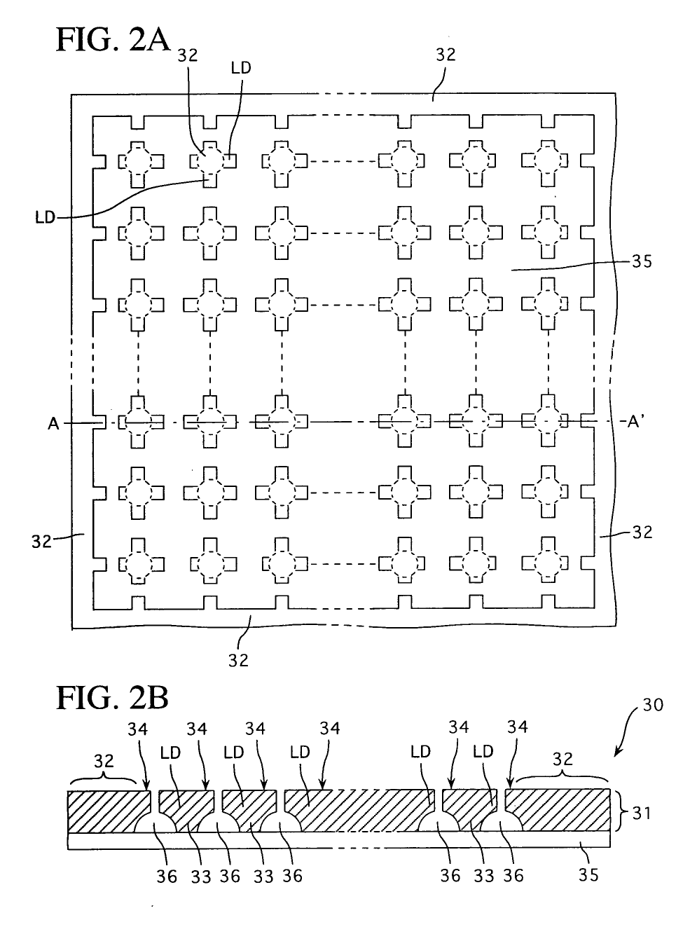

FIGS. 2A and 2B schematically show a constitution of a lead frame according to an embodiment of the present invention. FIG. 2A shows a constitution of part of the lead frame as viewed in a plane, and FIG. 2B shows a cross-sectional structure of the lead frame taken along a line A-A′ of FIG. 2A.

In FIGS. 2A and 2B, the reference numeral 30 denotes a lead frame used as a substrate of a leadless package (semiconductor device) such as QFN. The lead frame 30 includes a base frame 31 basically obtained by etching or stamping a metal plate. In the base frame 31, reference numeral 32 denotes a frame portion. In a region surrounded by the frame portion 32, a plurality of leads LD are discontinuously arranged to be orthogonal to each other (namely, in a lattice pattern). Portions (surrounded by broken lines), where the leads LD intersect each other while being independently arranged, constitute land-like conductor portions 33. In other words, in the region surrounded by the frame portion 32, the land-like conductor portions 33, each being formed of part of the corresponding lead LD at the portion where each lead LD intersects each other, are arranged in a lattice pattern.

The land-like conductor portions 33 arranged in a lattice pattern are, as described later, basically used as external connection terminals of each package (semiconductor device), but some of the conductor portions 33 (the number of land-like conductor portions 33 in accordance with size of each semiconductor element (chip) to be mounted) are used as a substitute for a die-pad portion.

A metal film 34 is formed on the entire surface of the base frame 31, an adhesive tape 35 is attached to a surface (lower surface in the example of FIG. 2B) of the base frame 31 opposite to the side where the semiconductor element (chip) is mounted. The adhesive tape 35 supports the frame portion 32 and the land-like conductor portions 33. In addition, the adhesive tape 35 has a function of supporting the land-like conductor portions 33 so that the individual land-like conductor portions 33 which are separated from the frame portion 32 do not fall off when portions which connect the frame portion 32 and the land-like conductor portions 33 (portions where the leads LD intersect each other), and portions which connect the land-like conductor portions 33 each other, are cut off in the manufacturing process of the lead frame 30 to be described later. This attachment (taping) of the adhesive tape 35 is performed as a countermeasure for preventing leakage (also called “mold flush”) of sealing resin to the back surface of the frame in molding in the assembly process of packages to be performed in a later stage.

Reference numeral 36 denotes a recess portion formed by half etching as described later. The position where the recess portion 36 is formed is selected at a portion other than the frame portion 32 and the portion where the leads LD intersect each other, namely, the portion connecting the frame portion 32 and the land-like conductor portions 33 or the portion connecting the land-like conductor portions 33 each other.

In the example shown in FIG. 2A, the portion where the leads LD intersect each other is made larger than the lead width, and can be easily formed by patterning the metal plate with etching or the like. Thus the portion where the leads LD intersect each other is made larger, and accordingly, the wire bonding can be easily performed in the assembly process of packages to be performed in the later stage.

The number of land-like conductor portions 33 arranged in a lattice pattern is properly selected depending on the sizes of the chips to be mounted, the number of chips to be mounted, the number of external connection terminals necessary for the chips, and the like.

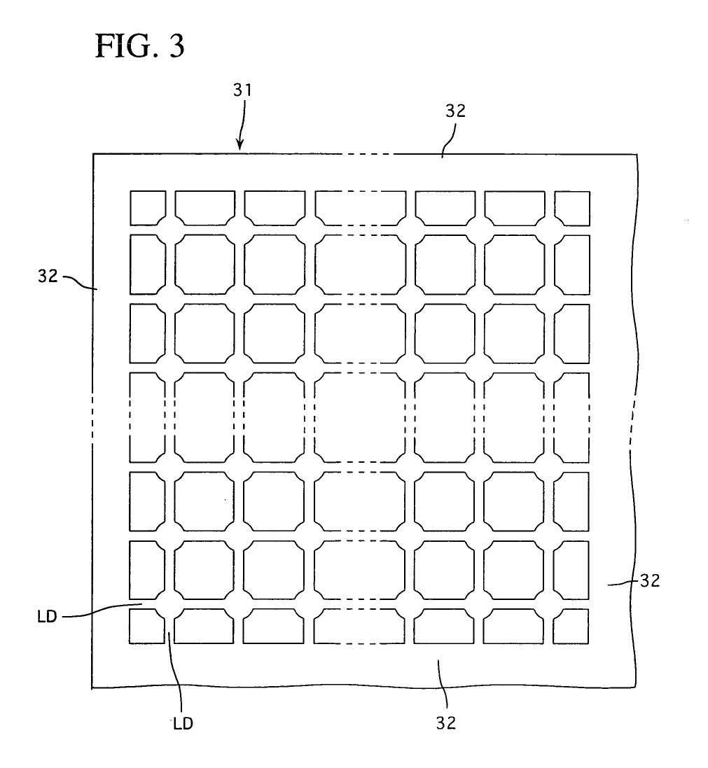

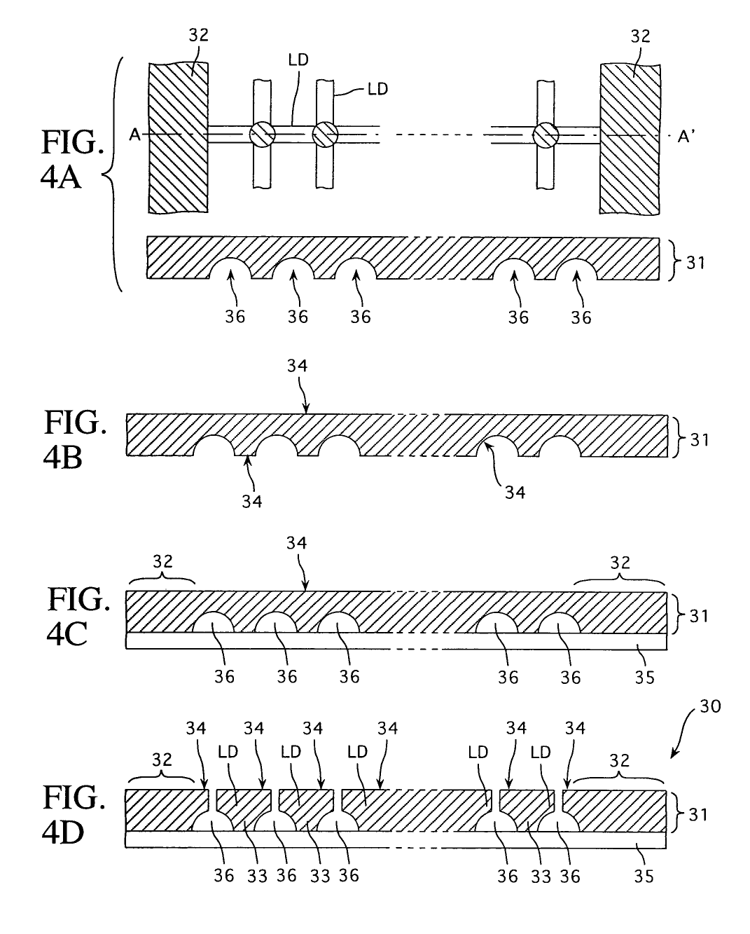

Next, a method of manufacturing the lead frame 30 according to the. embodiment will be described with reference to FIG. 3 and FIGS. 4A to 4D sequentially showing an example of the manufacturing process. First, in the first step (see FIG. 3), a metal plate is etched or stamped to form the base frame 31.

The base frame 31 to be formed, as schematically shown in FIG. 3, has a structure including the frame portion 32 and the plurality of leads LD which are continuously arranged to be orthogonal to each other (namely, in a lattice pattern) within the region surrounded by the frame portion 32 and also connected to the frame portion 32.

As a material of the metal plate, for example, copper (Cu), Cu based alloy, iron-nickel (Fe—Ni) alloy, Fe—Ni based alloy, or the like, is used. Selected thickness of the metal plate (base frame 31) is approximately 200 μm.

In the next step (see FIG. 4A), the recess portions 36 are formed by half etching in predetermined portions of one surface (the lower surface in the cross-sectional structure of the lower view in the example shown in FIG. 4A) of the base frame 31.

The predetermined portions (portions where the recess portions 36 are formed) are selected in portions other than the hatched portions (frame portion 32 and portions where the leads LD intersect each other) in the planer constitution shown in the upper view.

The half etching can be performed, for example, by wet etching after the portions other than the above predetermined portions of the base frame 31 are covered with a mask (not shown). The recess portions 36 are formed to have a depth of approximately 160 μm.

In the next step (see FIG. 4B), the metal film 34 is formed by electroplating on the entire surface of the base frame 31 with the recess portions 36 formed.

For example, using the base frame 31 as an electricity supply layer, the surface of the base frame 31 is plated with nickel (Ni) for improving adhesion, and palladium (Pd) is plated on the Ni layer for improving conductivity, followed by gold (Au) flash on the Pd layer so as to form the metal film (Ni/Pd/Au) 34.

In the next step (see FIG. 4C), the adhesive tape 35 including epoxy resin, or polyimide resin is attached to the surface of the base frame 31 where the recess portions 36 are formed (taping).

In the final step (see FIG. 4D), the portions of the lead LD where the recess portions 36 are formed are cut off, for example, with a punch, a blade, or the like. The lead frame 30 (FIGS. 2A and 2B) according to the embodiment is thus produced.

As described above, according to the lead frame 30 of this the embodiment and the method of manufacturing the same, the land-like conductor portions 33, each being formed of part of the corresponding lead LD at the portion where each lead LD intersects each other, are arranged in a lattice pattern within the region surrounded by the frame portion 32. Accordingly, some of the land-like conductor portions 33 can be utilized as a substitute for the die-pad portion in accordance with the size of the semiconductor element (chips) to be mounted.

Namely, instead of the prior art die-pad portion whose size is fixedly determined in accordance with the chip size, the plurality of land-like conductor portions 33 are arranged in a lattice pattern, and the desired number of land-like conductor portions 33 thereamong can be used for the die-pad portion. Accordingly, it is possible to cope with a plurality of chip sizes using a single lead frame 30, independently of the chip sizes.

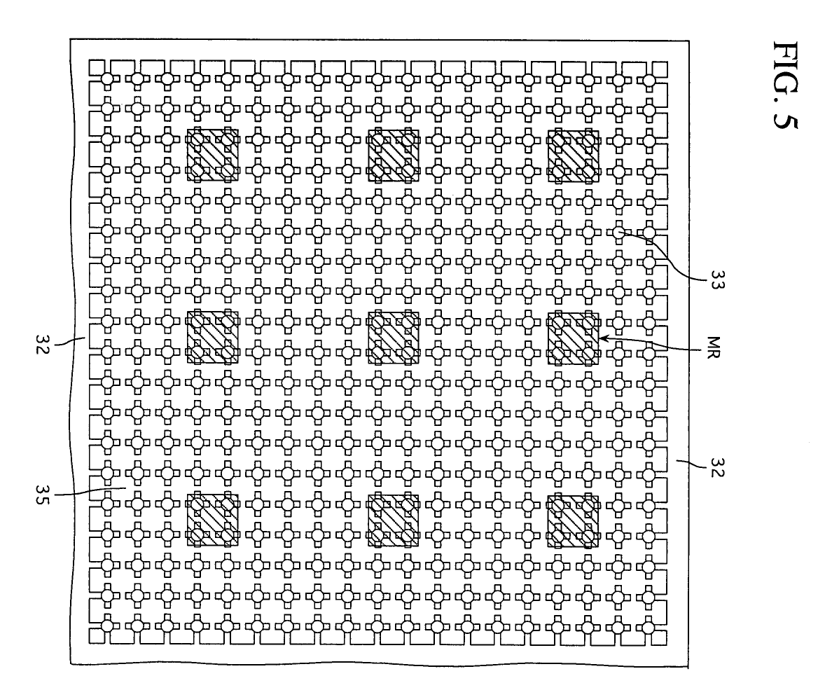

Therefore, one lead frame 30 allows a plurality of chips to be mounted thereon. An example of arrangement of the chips in such a case is shown in FIG. 5. In FIG. 5, hatched portion MR indicates a semiconductor element (chip) mounting region, namely, a region corresponding to the die-pad portion. In the illustrated example, it is assumed that each chip to be mounted has 32 pins. Accordingly, a region which is defined by thirty-six land-like conductor portions 33 arranged in a 6 by 6 matrix is allocated to each chip, and four land-like conductor portions 33 in the center thereof are utilized as a substitute for the die-pad portion. The illustrated example shows an arrangement in the case where nine chips having the same size are mounted. Although not shown in FIG. 5, the plurality of chips to be mounted do not necessarily have the same size and may have different sizes.

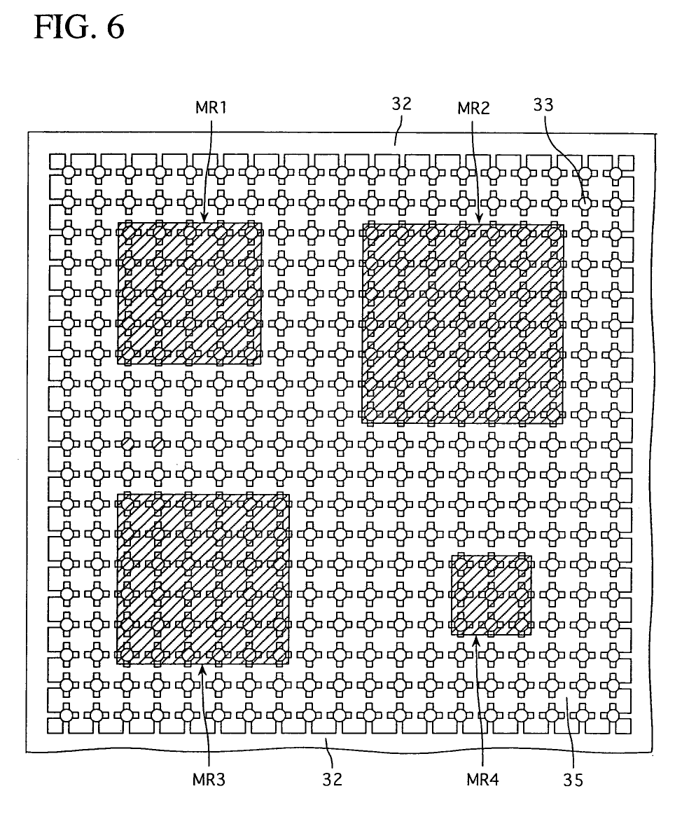

Also, since the lead frame 30 allows chips having arbitrary sizes to be mounted thereon, a plurality of chips can be mounted in a single package to be finally formed as a semiconductor device (manufacturing of a so-called “multi-chip package”). An example of arrangement of chips in such a case is shown in FIG. 6. In FIG. 6, hatched portions MR1 to MR4 indicate semiconductor element (chip) mounting regions (regions corresponding to the die-pad portions) as in the example shown in FIG. 5. The illustrated example shows an arrangement in the case where four chips having different chip sizes are mounted in the same package.

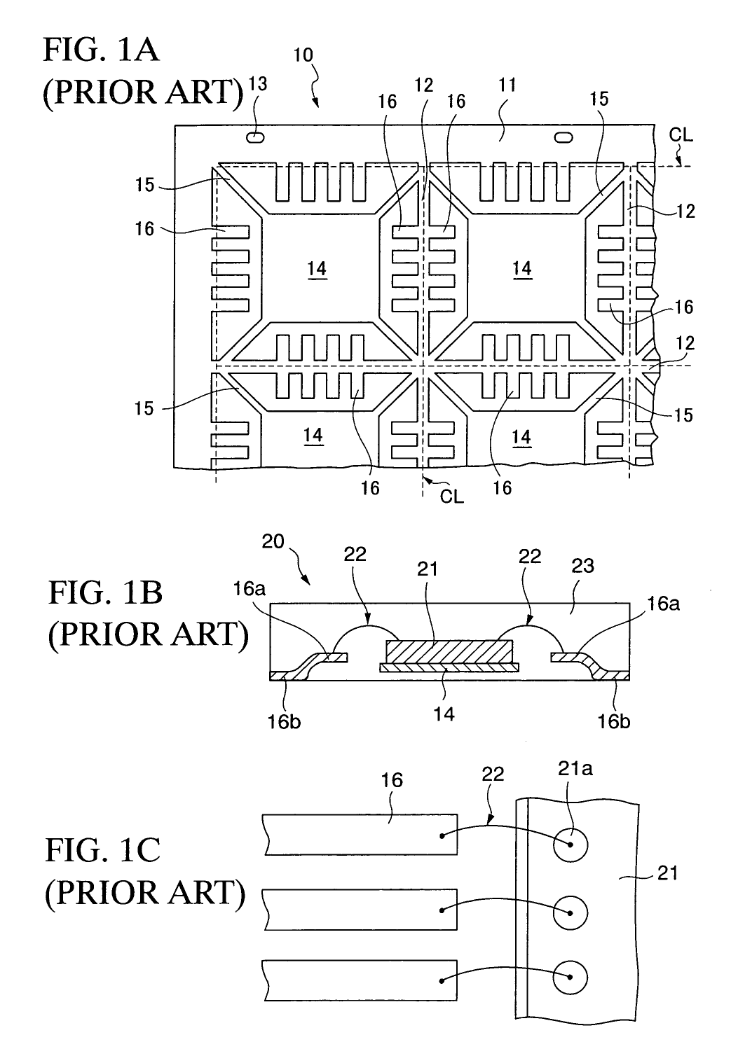

Furthermore, the plurality of land-like conductor portions 33 (some of them are substituted for the die-pad portion) used as the external connection terminals are arranged in a lattice pattern within the region surrounded by the frame portion 32. Accordingly, compared with the prior art lead frame (see FIG. 1) with the beam-shaped leads 16 (corresponding to the external connection terminals) extending in a comb shape from the frame portions 11, 12 toward the die-pad portion 14, the number of terminals can be relatively increased (increase in the number of terminals).

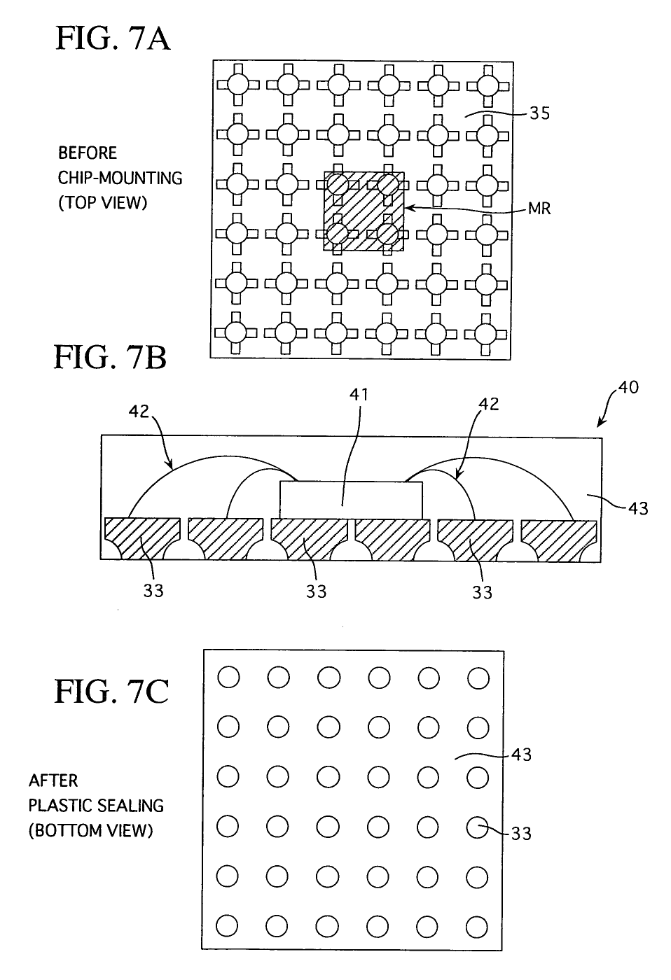

FIGS. 7A to 7C schematically show an example of the semiconductor device manufactured using the lead frame 30 of the above embodiment, the semiconductor device having the QFN package structure. FIG. 7A shows a constitution of the state before mounting a chip in the package assembly process as viewed in a plane (top view); FIG. 7B shows a constitution of the semiconductor device 40 as viewed in a cross section; and FIG. 7C shows a constitution of the state after plastic sealing in the assembly process as viewed in a plane (bottom view).

The constitution shown in FIG. 7A corresponds to a region (containing the chip mounting region MR) defined by thirty-six land-like conductor portions 33 arranged in a 6 by 6 matrix in the constitution shown in FIG. 5. Therefore, the number of pins of the chip mounted on this package (semiconductor device 40) is assumed to be thirty-two.

In the semiconductor device 40 shown in FIG. 7B, reference numeral 41 denotes a semiconductor element (chip) mounted on four land-like conductor portions 33 used as a substitute for the die-pad portion; reference numeral 42 denotes a bonding wire connecting each electrode terminal (pin) of the chip 41 to the corresponding land-like conductor portion 33 (external connection terminal); and reference numeral 43 denotes sealing resin for protecting the chip 41, the bonding wire 42, and the like.

The method of manufacturing the semiconductor device 40 (QFN package) is basically the same as that of the prior art QFN package, and thus the detailed description will be omitted. Basically, the method of manufacturing the semiconductor device 40 includes a step of mounting the chip 41 on the four land-like conductor portions 33 (substitute for the die-pad portion) of the lead frame 30, a step of electrically connecting the electrode terminals of the chip 41 to the corresponding land-like conductor portions 33 (external connection terminals) with the bonding wires 42, a step of sealing the chip 41, the bonding wires 42, and the like, with sealing resin 43 (mass molding or individual molding), and a step of dividing the lead frame (base frame 31) into packages (semiconductor devices) with a dicer or the like, after removing the adhesive tape 35.

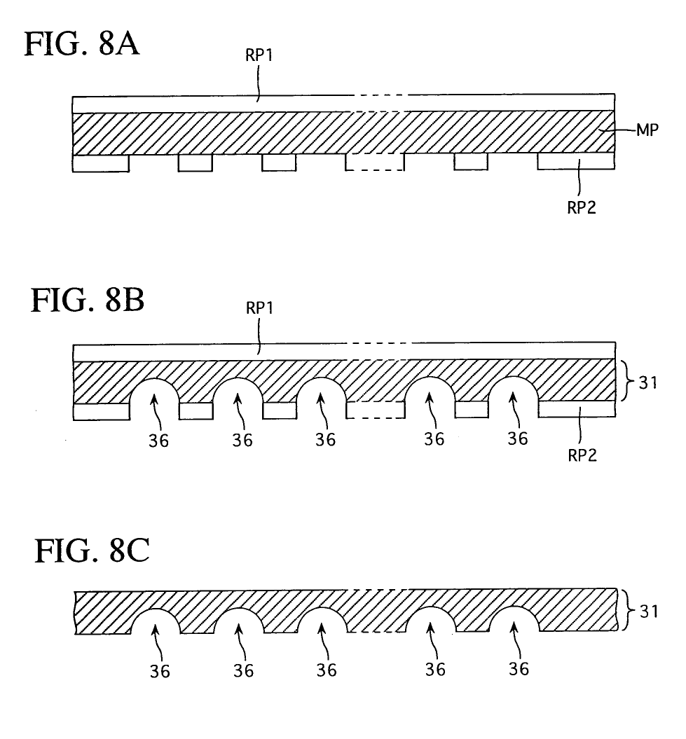

In the method of manufacturing the lead frame 30 according to the above embodiment (FIG. 3 and FIGS. 4A to 4D), the base frame 31 and the recess portions 36 are formed in the different steps (FIG. 3, FIG. 4A), but the base frame 31 and the recess portions 36 can also be formed in one step. An example of the manufacturing process in such a case is shown in FIGS. 8A to 8C.

In the method illustrated in FIGS. 8A to 8C, first, both surfaces of a metal plate MP (for example, Cu or Cu-based alloy plate) are coated with etching resist, and the resist is patterned using masks (not-shown), each being patterned into a predetermined shape to form resist patterns RP1 and RP2 (FIG. 8A).

In this case, as for the resist pattern RP1 of the upper side (the side where the semiconductor element (chip) is mounted), the resist is patterned so as to cover regions of the metal plate MP corresponding to the frame 32, the portions where the leads LD intersect each other, and the portions mutually connecting the frame portions 32 and the leads LD. On the other hand, as for the resist pattern RP2 on the lower side, the resist is patterned so as to cover regions of the metal plate MP corresponding to the frame portion 32 and the portions where the leads LD intersect each other and expose regions corresponding to portions of the metal plate MP to be the recess portions 36.

After the both surfaces of the metal plate MP are covered with the resist patterns RP1 and RP2 in such a manner, the leads LD in the pattern as shown in FIG. 3 and the recess portions 36 are simultaneously formed by etching (for example, wet etching) (FIG. 8B).

Furthermore, the etching resist (RP1, RP2) is removed to obtain the base frame 31 having the structure as shown in the lower view of FIG. 4A (FIG. 8C). The subsequent steps are the same as those after the step shown in the FIG. 4B.

According to the method illustrated in FIG. 8, since the base frame 31 and the recess portions 36 are formed in one step, the process can be simplified compared with the case of the above embodiment (FIG. 3 and FIGS. 4A to 4D).

What is claimed is:

1. A lead frame comprising:
a frame portion; and
a plurality of land-like conductor portions arranged in a lattice pattern within a region surrounded by the frame portion,
wherein the frame portion and the plurality of landlike conductor portions are supported by an adhesive tape.

2. The lead frame according to claim 1, wherein a plurality of leads are discontinuously arranged in a direction orthogonal to each other within the region surrounded by the frame portion, and each of the plurality of land-like conductor portions is formed of part of the corresponding lead at a portion where each lead intersects each other.

3. The lead frame according to claim 2, wherein the portion where each lead intersects each other is formed to be larger than a width of the corresponding lead.

4. A method of manufacturing a lead frame, comprising the steps of:
forming a base frame including a frame portion and a plurality of leads which are arranged in a direction orthogonal to each other within a region surrounded by the frame portion and connected to the frame portion, by etching or stamping a metal plate;
forming recess portions by half etching, at portions other than portions where the leads intersect each other and the frame portion, of one surface of the base frame;
attaching an adhesive tape to the surface of the base frame where the recess portions are formed; and
cutting off portions of the leads where the recess portions are formed.

5. The method according to claim 4, further comprising a step of forming a metal film on an entire surface of the base frame after forming the recess portions, and before attaching the adhesive tape.

6. A method of manufacturing a lead frame, comprising the steps of:
forming a base frame including a frame portion and a plurality of leads and forming recess portions at portions other than portions where the leads intersect each other and the frame portion, of one surface of the base frame, by simultaneously etching both surfaces of a metal plate using resists patterned in a predetermined shape on the both surfaces of the metal plate, the plurality of leads being arranged in a direction orthogonal to each other within a region surrounded by the frame portion and connected to the frame portion;
attaching an adhesive tape to the surface of the base frame where the recess portions are formed; and
cutting off portions of the leads where the recess portions are formed.

7. The method according to claim 6, further comprising a step of forming a metal film on an entire surface of the base frame after forming the recess portions, and before attaching the adhesive tape.
